(19) United States
(12) Patent Application Publication
(10) Pub. No.: US 2008/0012608 A1
(43) Pub. Date: Jan. 17, 2008

(54) Inductive load driving circuit

(76) Inventors: Atsushi Sudoh, Saitama (JP); Yoshinori Okada, Oita (JP); Seiji Murakami, Oita (JP); Atsuhiro Miwata, Oita (JP)

Correspondence Address: TEXAS INSTRUMENTS INCORPORATED, P O BOX 655474, M/S 3999, DALLAS, TX, 75265, US

(21) Appl. No.: 11/327,620

(22) Filed: Jan. 6, 2006

(30) Foreign Application Priority Data
Jan. 7, 2005 (JP) 2005-002730

(51) Int. Cl. H03K 3/00

(52) U.S. Cl. 327/108

(57) ABSTRACT

Objective To provide a current driving circuit that can improve the driving current setting accuracy. Means to solve
Transistors 1-1-1-n of bias voltage generating circuit 1 and transistors 3-1-3-8 of output circuits 2-1-2-160 are distributed and formed in a common region on a semiconductor substrate. In this way, the threshold voltage of the synthetic transistor constituted by transistors 1-1-1-n connected in parallel with each other is close to the average threshold voltage of transistors 3-1-3-8 of output circuits 2-1-2-160. As a result, the error in threshold voltage between this synthetic transistor and transistors 3-1-3-8 of output circuits 2-1-2-160 is about half the variation in threshold voltage of transistors 3-1-3-8 of output circuits 2-1-2-160. In other words, the error in threshold voltage of the transistors that constitute the current mirror circuit can be reduced.

### TECHNICAL FIELD

The present invention pertains to a current driving circuit used for driving the pixels of a display panel, for example.

### BACKGROUND TECHNOLOGY

FIG. 11 is a diagram illustrating a configuration example of the main parts in a general current driver IC that drives organic EL panel. As shown in FIG. 11, the conventional current driver IC has a reference current part U1 and an output circuit part U2.

Reference current part U1 has n-channel MOS transistor Qa and current source CCa.

Output circuit part U2 has 160 output circuits U2-1-U2-160 corresponding to 160 output channels.

One of the terminals of current source CCa is connected to power supply voltage AVDD via an external resistor Ra, and the other terminal is connected to the drain of transistor Qa. Current source CCa outputs reference current Iref to the drain of transistor Qa.

The drain and gate of transistor Qa are connected to common node Na, and its source is connected to reference potential AVSS.

Output circuit U2-i (i can be any integer in the range of 1-160) has plural transistors Qb (only one transistor is shown in FIG. 11 as an example) that constitute a current mirror circuit along with transistor Qa, a switch circuit (not shown in the figure), and output terminal Toi.

The gate of each transistor Qb is connected to a common node Na. The source is connected to reference potential AVSS. Also, the drain of each transistor Qb is connected to output terminal Toi via the switch circuit.

The switch circuit connects the drain of each transistor Qb to output terminal Toi according to the pixel data, which are not shown in the figure and designate the driving currents of the pixels (organic EL elements).

Output circuits U2-1-U2-160 are formed in parallel with one another on a semiconductor substrate in the same order as that of the output channels in order to prevent differences in the driving current between the adjacent output channels under the influence of the variations in the characteristics of the circuit elements. Consequently, the chip shape of current driver IC becomes a rectangular shape extended in the arrangement direction of output circuits U2-1-U2-160.

Also, as shown in FIG. 11, reference current part U1 is usually arranged in the head or at the end of the array of output circuits U2-1-U2-160.

In the aforementioned configuration, reference current Iref corresponding to the resistance of external resistor Ra flows through current source CCa. When reference current Iref flows through transistor Qa, the gate voltage of transistor Qa corresponding to reference current Iref is generated at node Na.

Since the voltage at said node Na is applied to the gates of transistors Qb, a current proportional to reference current Iref flows through transistors Qb. The current flowing through transistors Qb is proportional to the size ratio between transistors Qa and Qb.

On the other hand, in each output circuit U2-i, among the internal plural transistors Qb, the transistors selected on the basis of the pixel data are connected to terminal Toi. As the number of transistors Qb selected to output terminal Toi is increased, the driving current flowing through output terminal Toi becomes larger, and the brightness of the pixel is increased.

For example, if the pixel data has 8 bits, output circuit U2-i has transistors Qb having 8 types of size ratios (x1, x2, x4, x8, x16, x32, x64, x128). When connection between these 8 types of transistors and output terminal Toi is turned on or off corresponding to the pixel data, brightness with 256 gradations can be realized.

### DISCLOSURE OF THE INVENTION

Problems to be Solved by the Invention

Generally, however, in an active organic EL panel, the driving currents of the pixels are very small. For example, the upper limit of the current is in the range of several μA-tens of μA, and it is necessary to generate 256 stages of driving current. On the other hand, if the current difference between adjacent output channels exceeds several %, the image quality will be affected adversely. Therefore, it is necessary to suppress current variations as much as possible. Consequently, a very high current setting accuracy is required for the current driver IC used for organic EL panel.

The common methods for suppressing the current variation between output channels include adjusting the sizes of the transistors and designing the transistors to the same shape. However, even if the aforementioned measures are taken, since variations in the characteristics of the elements in the plane of a wafer occurring during the manufacturing process are inevitable, the variation is still a problem when comparison is made between semiconductor chips.

FIG. 12 is a diagram explaining the variations in the element characteristics in the plane of the wafer.

As shown in FIG. 12(A), plural semiconductor chips are usually cut out from one wafer. For example, in the case shown in FIG. 12(B), the threshold voltage Vth of transistor varies corresponding to the position on the arrow line Y shown in FIG. 12(A). This variation changes for each processed wafer. Also, the period of the variation and the tendency of the variation amount change corresponding to the type of manufacturing process.

When threshold voltage Vth varies as described above, the current flowing through transistor Qb in said current mirror circuit (Qa, Qb) varies. For example, as shown in FIG. 12(C), the variation tendency of current I flowing through transistors Qb is different for the IC chips (such as IC_A and IC_B) cut out from different locations on the same wafer.

On the other hand, in a conventional current driver IC, reference current part U1 is arranged in the end part of a semiconductor chip having a rectangular shape. In the example shown in FIG. 11, reference current part U1 is arranged adjacent to output circuit U2-1 corresponding to the first output channel.

Therefore, the threshold voltage of transistor Qa shows relatively good consistency with the threshold voltage of transistor Qb of output circuit U2-1. If the size ratio between transistors Qa and Qb is 1:1, the current of this transistor Qb is almost equal to reference current Iref.

However, as the number of output channels increases and the distance from reference current part U1 increases, since the correlation of the threshold voltage between transistors Qa and Qb decreases, as shown in FIG. 13, the current of transistor Qb might vary significantly from reference current Iref. The amount of the variation from said reference current Iref corresponds to the variation of the threshold voltage over the entire rectangular semiconductor chip.

Plural IC chips with current drivers are used for a relatively large organic EL panel. In this case, if there is difference in current between the IC chips, as shown in FIG. 14, there will be a difference in brightness on a single screen. In particular, if there is large difference in driving current in the boundary part of the panel driven by different IC chips, vertical stripes will appear on the screen to severely deteriorate the image quality.

Conventionally, the method of finely adjusting the resistance of external resistor R for each IC chip to adjust reference current Iref and the method of selecting IC chips with small current variations have been adopted in order to solve the problem of differences in brightness. These methods, however, have low mass productivity since fine adjustment of elements and selection of IC chips not only increase the operation burden but also adversely affect the yield.

The purpose of the present invention is to solve the aforementioned problems by providing a current driving circuit that can improve the driving current setting accuracy.

Means to Solve the Problems

The current driving circuit of a first aspect of the present invention has a reference current generating circuit that generates a reference current, a bias voltage generating circuit that includes plural first transistors connected in parallel with one another, inputs the aforementioned reference current to the parallel circuit of the first transistors, generates a bias voltage corresponding to the aforementioned reference current across the parallel circuit, and has a current corresponding to the bias voltage flowing through each of the first transistors, and plural second transistors that generate driving current corresponding to the bias voltage generated in the aforementioned bias voltage generating circuit. The aforementioned plural first transistors and the aforementioned plural second transistors are formed and distributed in a common region on a semiconductor substrate.

For the aforementioned first aspect, the aforementioned plural first transistors and plural second transistors can be arranged in one or more rows extending in the length direction of the aforementioned common region.

For the aforementioned first aspect, the one or more rows of the aforementioned first transistors and the one or more rows of the aforementioned second transistors can be arranged alternately in the aforementioned common region.

For the aforementioned first aspect, the aforementioned first and second transistors can also be arranged at equal intervals in the rows extending in the aforementioned length direction. Or, at least some of the aforementioned plural first transistors can be arranged in the same row as the aforementioned second transistors.

For the aforementioned first aspect, some of the aforementioned plural first transistors can be formed at one or both ends of the row of the aforementioned second transistors.

The current driving circuit of the second viewpoint of the present invention has a reference current generating part, which has plural first transistors connected in parallel with one another and generates a reference current, and plural driving current supply parts that have second transistors that are connected to the aforementioned plural first transistors, respectively, and that supply driving currents corresponding to the aforementioned reference current. The aforementioned plural driving current supply parts are arranged along the length direction of a rectangular substrate. The aforementioned plural first transistors are distributed and arranged along the length direction of the aforementioned semiconductor substrate.

For the aforementioned second aspect, the aforementioned plural first transistors can be distributed and arranged in a region adjacent to the region where the aforementioned plural driving current supply parts are arranged.

For the aforementioned second aspect, the aforementioned plural first transistors and the aforementioned plural second transistors can be mixed and are distributed and arranged along the length direction of the aforementioned semiconductor substrate.

For the aforementioned second aspect, the aforementioned plural first transistors and the aforementioned second transistors can constitute a current mirror circuit.

### EFFECT OF THE INVENTION

According to the present invention, the accuracy of the driving currents set on the basis of the reference current can be improved. In this way, even if there are circuits formed on different semiconductor chips, the variation in driving current between the two chips can be reduced if an equal reference current is applied.

### Preferred Embodiment of the Invention

In the following, the embodiment of the present invention will be explained on the basis of figures.

FIG. 1 shows an example of the configuration of the current driving circuit disclosed in the present invention.

The current driving circuit shown in FIG. 1 is a circuit that drives the pixels of a display panel, such as an organic EL panel. It has 160 output channels (the first-160^{th} output channels).

The current driving circuit shown in FIG. 1 has driving current generating circuit 10, reference current generating circuit 20, equivalent to the reference current generating circuit of the present invention, latch circuits 30 and 40, shift register 50, driving currents output terminals To1-To160, terminal T1 used for connecting external resistor R1, terminal T2 used for inputting pixel data, terminal T3 used for inputting data writing pulse, and terminal T4 used for inputting clock signal.

Shift register 50 shifts the data writing pulse (WRITE) input to terminal T3 sequentially corresponding to the clock signal CLK input to terminal T4, generates a data writing pulse corresponding to each of the 1^{st}-160^{th} output channels, and outputs it to latch circuit 40.

In response to the data writing pulse output twin shift register 50 corresponding to each of the 1^{st}-160^{th} output channels, latch circuit 40 sequentially inputs the pixel data of 160 channels of the 1^{st}-160^{th} output channels input serially from terminal T2 and outputs the data to latch circuit 30.

After a given certain horizontal scanning line on the display panel is driven and the next horizontal scanning line is about to be driven, latch circuit 30 latches the pixel data of 160 channels output from latch circuit 40 and outputs the data to driving current generating circuit 10.

Reference current generating circuit 20 generates reference current Iref corresponding to the resistance of external resistor R1 connected between terminal T1 and power supply voltage AVDD and supplies it to driving current generating circuit 10.

Driving current generating circuit 10 outputs the respective driving currents corresponding to the pixel data of 160 channels kept in latch circuit 30 from output terminals T01-To160 of the 160 channels. Also, the reference value of the driving currents is set on the basis of the supplied reference current Iref.

FIG. 2 shows an example of the configuration of driving current generating circuit 10.

Driving current generating circuit 10 shown in FIG. 2 has a bias voltage generating circuit 1 equivalent to the bias voltage generating circuit of the present invention and current output part 2.

Bias voltage generating circuit 1 has n (n is any integer greater than 1) n-channel MOS type transistors 1-1-1-n.

Transistors 1-1-1-n are one embodiment of the first transistors of the present invention.

Transistors 1-1-1-n are connected in parallel between node NG, which inputs reference current Iref from reference current generating circuit 20 and reference potential AVSS. The gates of transistors 1-1-1-n are connected in common to node NG.

The parallel circuit of said transistors 1-1-1-n generates a bias voltage corresponding to reference current Iref at node NG.

A current corresponding to the bias voltage generated at node NG flows through each of transistors 1-1-1-n.

Since the drains of transistors 1-1-1-n are connected to one another, as are their sources and gates, a synthetic transistor can be formed. The drain and gate of this synthetic transistor are connected to node NG, and its source is connected to reference potential AVSS. The gate-source voltage of the synthetic transistor that is formed corresponding to reference current Iref is generated at node NG.

Also, transistors 1-1-1-n are distributed and formed in a prescribed region on a semiconductor substrate along with the transistors (3-1-3-8) of output circuits (2-1-2-160) be described later. Consequently, the characteristics (threshold voltage, etc.) of the synthetic transistor constituted by transistors 1-1-1-n are similar to the averages of the characteristics of the transistors formed in that region.

Current output part 2 has 160 output circuits 2-1-2-160.

Output 2-i (i is any integer in the range of 1-160) has 8 types of transistors that constitute a current mirror circuit along with the synthetic transistor of transistors 1-1-1-n. Output circuit 2-i generates the driving current for the ith output channel by synthesizing the currents generated by the 8 types of transistors corresponding to the pixel data of latch circuit 30.

FIG. 3 shows an example of the configuration of output circuit 2-i.

The output circuit 2-i shown in FIG. 3 has n-channel MOS type transistors 3-1-2-8 and switches 4-1-4-8.

Transistors 3-1-3-8 are one embodiment of the second transistors of the present invention.

Transistor 3-j (j is any integer in the range of 1-8) generates driving current corresponding to the bias voltage at node NG.

The gate of transistor 3-j is connected to node NG. Its source is connected to reference potential AVSS. Its drain is connected to output terminal Toi via switch 4-j.

The driving current generated in transistor 3-j flows to output terminal Toi via switch 4-j.

Switches 4-1-4-8 are turned on or off corresponding to the 8-bit pixel data output from latch circuit 30 to output circuit 2-i.

The currents flowing through transistors 3-1-3-8 have weights proportional to the power of 2. That is, if the current of transistor 3-1 is “1”, a current of ‘2’ flows through transistor 3-2, a current of ‘4’ flows through transistor 3-3, a current of ‘8’ flows through transistor 3-4, a current of ‘16’ flows through transistor 3-5, a current of ‘32’ flows through transistor 3-6, a current of ‘64’ flows through transistor 3-7, and a current of ‘128’ flows through transistor 3-8.

Consequently, the synthetic current flowing to output terminal Toi can be adjusted to 256 stages by turning on/off switches 4-1-4-8 corresponding the pixel data.

The aforementioned current ratio of transistors 3-1-3-8 can be realized by connecting transistors with the same structure as transistors 1-1-1-n in parallel with one another. For example, if one transistor of the same type as transistors 1-1-1-n is used for transistor 3-1, the number of transistors connected in parallel is 2 for transistor 3-2, 4 for transistor 3-3, 8 for transistor 3-4, 16 for transistor 3-5, 32 for transistor 3-6, 64 for transistor 3-7, and 128 transistor 3-8.

In this case, transistors 1-1-1-n that constitute the current mirror circuit and transistors 3-1-3-8 have exactly the same structure. Consequently, the layout structure, in which these transistors are distributed and formed in a common region, becomes simple (see FIGS. 5-8 to be described later).

The aforementioned current ratio of transistors 3-1-3-8 can also be realized by setting the size ratio of transistors 3-1-3-8 according to the current ratio.

In the following, the operation of the current driving circuit having the aforementioned configuration will be explained.

The pixel data of the 1^{st}-160^{th} output channels input serially from terminal T2 are sequentially input and latched into latch circuit 40 corresponding to the data writing pulse for the 160 output channels generated in shift register 50.

When driving of the current horizontal scanning line ends and it is ready to drive the next horizontal scanning line, the pixel data of the 160 channels latched into latch circuit 40 are transferred to latch circuit 30. The on/off state of each switch (4-1-4-8) of output circuits 2-1-2-160 is set as a function of the pixel data transferred to latch circuit 30.

In output circuit 2-i, the mirror currents of transistors (3-1-3-8) connected switches (4-1-4-8) set to the on state are synthesized. The synthesized current is output as driving current to output terminal Toi.

In the following, the setting accuracy for driving current in the current driving circuit having the aforementioned configuration will be explained.

FIG. 4 is a diagram explaining variation in driving current.

FIG. 4(A) shows variation in driving current in the conventional circuit shown in FIG. 9.

FIG. 4(B) shows variation in driving current in the current driving circuit disclosed in this embodiment.

Symbol “TR1” represents the transistor that inputs reference current Iref in the current mirror circuit. It corresponds to transistor Qa in the conventional circuit shown in FIG. 9 and corresponds to transistors 1-1-1-n in the current driving circuit disclosed in this embodiment.

Symbol “TR2” represents the transistor that outputs the mirror current corresponding to the reference current in the current mirror circuit. It corresponds to transistor Qb in the conventional circuit shown in FIG. 9 and corresponds to transistors 3-1 3-8 of output circuits 2-1-2-160 in the current driving circuit disclosed in this embodiment.

The significant difference between the conventional circuit shown in FIG. 9 and the current driving circuit disclosed in this embodiment is the arrangement of transistors TR1 and TR2 that constitute the current mirror circuit.

In the conventional circuit shown in FIG. 9, transistors TR2 are arranged in parallel in the number sequence of the output channels in a rectangular region on a semiconductor substrate. Transistor TR1 is arranged at one end of the rectangular region (on the side of the first output channel).

Consequently, the characteristics of transistor TR1 well match the characteristics of transistor TR2 of the first output channel arranged nearby. However, as the number of the output channel increases and the distance between transistors TR1 and TR2 increases, the influence of the characteristic variation on the aforementioned wafer becomes more and more significant. As a result, the characteristics of the two transistors become different.

If the threshold voltage of transistor TR2 has a maximum variation of ΔV, the largest difference in threshold voltage between transistors TR1 and TR2 becomes ‘ΔV’.

The difference in threshold voltage between transistors TR1 and TR2 causes a difference in current between transistors TR1 and TR2. If the current difference between the two transistors is assumed to be ‘ΔI’ when the difference in threshold voltage is ‘ΔV’, as shown in FIG. 4(A), the current of transistor TR2 will have an error up to ‘ΔI’ with respect to reference current Iref.

On the other hand, in the current driving circuit disclosed in this embodiment, transistors TR1 and TR2 are distributed and formed in a common region on a semiconductor substrate. For example, as shown in FIG. 4(B), transistors TR1 are arranged in the horizontal direction from end to end of the rectangular region where transistors TR2 are formed.

In general, the semiconductor chip of a current driving circuit used for driving a display panel has a very flat rectangular shape with a length, for example, in the range of several mm-tens of mm because of the demand on circuit layout, which has plural output circuits arranged in parallel and adjacent to one another, and the assembly form of bonding semiconductor chips on the glass of the display panel.

Consequently, when transistors TR1 arranged in a widely distributed way in a rectangular region as shown in FIG. 4(B) are connected in parallel as shown in FIG. 2 to constitute a synthetic transistor, the characteristics of the synthetic transistor are close to the mean characteristics of the transistors formed in the rectangular region. If the symbols shown in FIG. 2 are used, the characteristics of the synthetic transistor constituted by transistors 1-1-1-n are similar to the results obtained by averaging the variations in the characteristics of transistors 3-1-3-8 formed in the same rectangular region.

Consequently, in the same way as shown in FIG. 4(A), if the threshold voltage of transistor TR2 has a maximum variation of ‘ΔV’, the difference in threshold voltage between transistors TR1 and TR2 becomes almost ‘ΔV/2’.

If the current difference between the two transistors is ‘ΔI’ when the threshold voltage difference is ‘ΔV’, as shown in FIG. 4(B), the current of transistor TR2 has an error of about ‘ΔI/2’ with respect to reference current Iref.

In other words, the error of the driving current flowing through transistor TR2 is almost half that of the conventional circuit shown in FIG. 9.

As described above, for the current driving circuit disclosed in this embodiment, the transistors 1-1-1-n of bias voltage generating circuit 1 and the transistors 3-1-3-8 of output circuit 2-1-2-160 are distributed and formed in a common region on a semiconductor substrate. In this way, the threshold voltage of the synthetic transistor constituted by transistors 1-1-1-n connected in parallel is close to the average of the threshold voltages of transistors 3-1-3-8 of output circuits 2-1-2-160. As a result, the error in threshold voltage between this synthetic transistor and the transistors 3-1-3-8 of output circuits 2-1-2-160 is about half the variation in threshold voltage in transistors 3-1-3-8 of output circuits 2-1-2-160.

Consequently, for the current driving circuit disclosed in this embodiment, compared with the conventional circuit shown in FIG. 9, the driving current setting accuracy can be improved since the error in threshold voltage of transistors (TR1, TR2) that constitute the current mirror circuit is reduced.

Also, since the driving current setting accuracy is improved, the driving currents of transistors 3-1-3-8 generated when a certain reference current Iref is supplied to bias voltage generating circuit 1 are similar to the certain reference current at a high accuracy. Consequently, if equal reference currents are applied to the current driving circuits formed on different semiconductor chips, the driving currents of the two semiconductor chips are similar to the given reference current with high precision. In other words, the variation in driving current between different semiconductor chips can be reduced.

Consequently, even if plural IC chips loaded with the current driving circuit disclosed in this embodiment are used to drive a display panel, since the variation in driving current between the IC chips is small, the difference in brightness on the display panel can be suppressed.

As a result, fine adjustment of circuit constants (fine adjustment of external resistance, etc.) or IC chip selecting operation performed for the conventional circuit and other operations performed because of the variation in driving current between IC chips can be omitted or reduced. Therefore, mass productivity can be increased.

In the following, a specific example of forming transistors 1-1-1-n and transistors 3-1-3-8 of output circuits 2-1-2-160 in a common region on a semiconductor substrate will be explained on the basis of FIGS. 5-8.

In the following explanation, each of transistors 1-1-1-n is simply referred to as ‘transistor TR1’, and each of transistors 3-1-3-8 of output circuits 2-1-2-160 is simply r to as ‘transistor TR2’.

FIG. 5 shows an example of arranging transistors TR1 in parallel with one another in an array.

In the example shown in FIG. 5, transistors TR1 are arranged in an array extending in the length direction of rectangular region AR1.

Also, transistors TR2 are arranged in plural rows extending in the length direction of region AR1.

As explained above, since the length of rectangular region AR1 is much larger than its width, the mean characteristics of transistors TR1 arranged in parallel in an array as shown in FIG. 5 are close to the results obtained by averaging the variations of the characteristics of transistors TR2.

Consequently, the characteristics of the synthetic transistor formed by arranging transistors TR1 shown in FIG. 5 in parallel with each other as shown in FIG. 2 are close to the mean characteristics of transistors TR2.

FIG. 6 shows an example of alternately arranging the rows of transistors TR1 and the rows of transistors TR2.

Transistors TR1 and TR2 are arranged to extend in the length direction of rectangular region AR1 in the same way as shown in FIG. 5.

In the example shown in FIG. 6, the rows of these transistors are alternately arranged. Consequently, compared with FIG. 5 in which the row of transistors TR1 and the rows of transistors TR2 are arranged separately, transistors TR1 and TR2 are mixed more uniformly. Consequently, the characteristics of the synthetic transistor of transistors TR1 are closer to the mean characteristics of transistors TR2 compared with the example shown in FIG. 5.

Also, in the examples shown in FIGS. 5 and 6, in each row extending in the length direction of region AR1, transistors TR1 and TR2 are arranged at equal intervals. In this way, since transistors TR1 and TR2 are arranged in a widely distributed manner in region AR1, the effect of bringing the characteristics of the synthetic transistor of transistors TR1 closer to the mean characteristics of transistors TR2 can be improved.

FIG. 7 shows an example of arranging transistors TR1 and TR2 in the same rows.

In the example shown in FIG. 7, at least some of transistors TR1 are arranged in the same rows as transistors TR2. Compared with the examples shown in FIGS. 5 and 6, transistors TR1 and TR2 can be mixed more uniformly this way. Consequently, the characteristics of the synthetic transistor of transistors TR1 are closer to the mean characteristics of transistors TR2.

FIG. 8 shows an example of forming some of transistors TR1 at the ends of the rows of transistors TR2.

As shown in FIG. 8, when some of transistors TR1 are formed at one or both ends of the rows of transistors TR2, the variations in the transistor characteristics in the length direction of the region AR1 and the variations in the transistor characteristics in the direction perpendicular to the length direction are added to the overall characteristics of transistors TR1. Consequently, the characteristics of the synthetic transistor of transistors TR1 are closer to the mean characteristics of transistors TR2 compared with the example shown in FIG. 5.

An embodiment of the present invention has been explained above. The present invention, however, is not limited to the aforementioned embodiment and includes several variations.

FIG. 5 shows an example of arranging transistors TR1 in one row. The present invention is not limited to this. For example, as shown in FIG. 9, it is also possible to arrange transistors TR1 in plural rows including the top and bottom of the rectangular semiconductor chip. As shown in FIG. 10, it is also possible to arrange transistors TR1 in a region including the peripheral part of the semiconductor chip.

FIG. 6 shows an example of arranging transistors TR1 and transistors TR2 alternately every other row. The present invention is not limited to this. It is also possible to alternate plural rows of transistors TR1 and/or transistors TR2.

In the aforementioned embodiment, examples of current driving circuits used for driving mainly monochromatic display panels have been explained. The present invention is not limited to this. For example, in the case of current driving circuits used for driving three colors (RGB) independently, three sets of the aforementioned circuit configuration for a single color can be used independently.

Also, in the aforementioned embodiment, a case of performing current driving for a display panels has been explained as an example. The present invention is not limited to this. The current driving circuit of the present invention can also be used to drive other devices that require driving currents for multiple channels besides display panels.

In the aforementioned embodiment, an example of using n-channel MOS transistors has been explained. However, it is also possible to use p-channel MOS transistors. In the aforementioned example of using n-channel MOS transistors, the driving currents flow from the, pixels to output circuits 2-1-2-160. However, when p-channel MOS transistors are used, on the contrary, the driving currents flow from output circuits 2-1-2-160 to the pixels. In this case, reference current generating circuit 20 and external resistor R1 can be connected to the side of reference potential AVSS.

Also, the transistors used in the present invention are not limited to the MOS type transistors. It is also possible to use bipolar transistors or other types of active elements.

The specific values (number of output channels, number of gradations, etc.) mentioned in the aforementioned embodiment are an example used for explaining the present invention. The present invention is not limited to these values. These values can be substituted with any other values.

Also, the relationship between the number of the transistors that constitute bias voltage generating circuit 1 and the number of output circuits of current output part 2 can be any relationship. For example, the two numbers can be equal to each other, or one number can be ½, ⅓, ¼, . . . of the other number.

### BRIEF EXPLANATION OF FIGURES

FIG. 1 shows an example of the configuration of the current driving circuit disclosed in an embodiment of the present invention.

FIG. 2 shows an example of the configuration of the driving current generating circuit.

FIG. 3 shows an example of the configuration of the output circuit.

FIG. 4 is a diagram explaining the variation in the driving current.

FIG. 5 shows an example of arranging the transistors of the bias voltage generating circuit in one row.

FIG. 6 shows an example of arranging rows formed by the transistors of the bias voltage generating circuit and rows formed by the transistors of the output circuit alternately.

FIG. 7 shows an example of arranging the transistors of the bias voltage generating circuit in the same row as the transistors of the output circuit.

FIG. 8 shows an example of arranging some of the transistors of the bias voltage generating circuit at the ends of the rows formed by the transistors of the output circuit.

FIG. 9 shows a modification example of arrangement of the transistors shown in FIG. 5.

FIG. 10 shows another modification example of arrangement of the transistors shown in FIG. 5.

FIG. 11 shows a constitution example of the main parts of a general current driver IC that drives organic EL panel.

FIG. 12 is a diagram explaining variations in the element characteristics in the plane of the wafer.

FIG. 13 shows an example of variation in driving current in different current driver IC.

FIG. 14 is a diagram explaining difference in brightness occurring when plural current drivers IC are used to drive an organic EL panel.

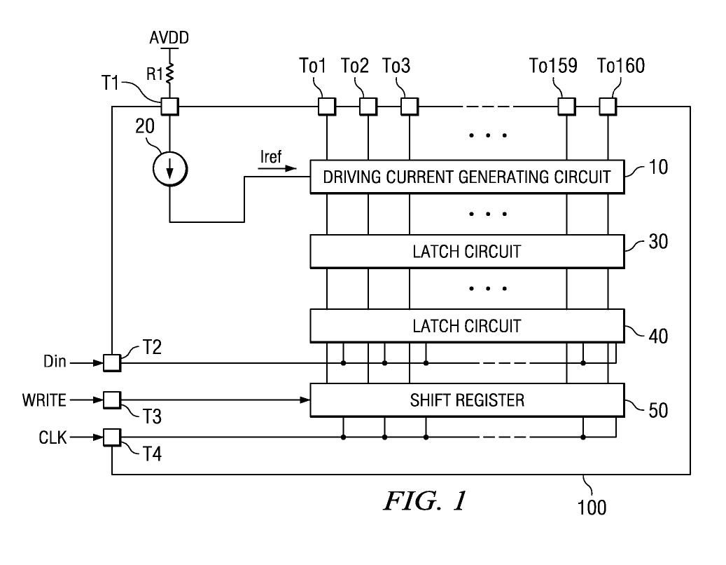

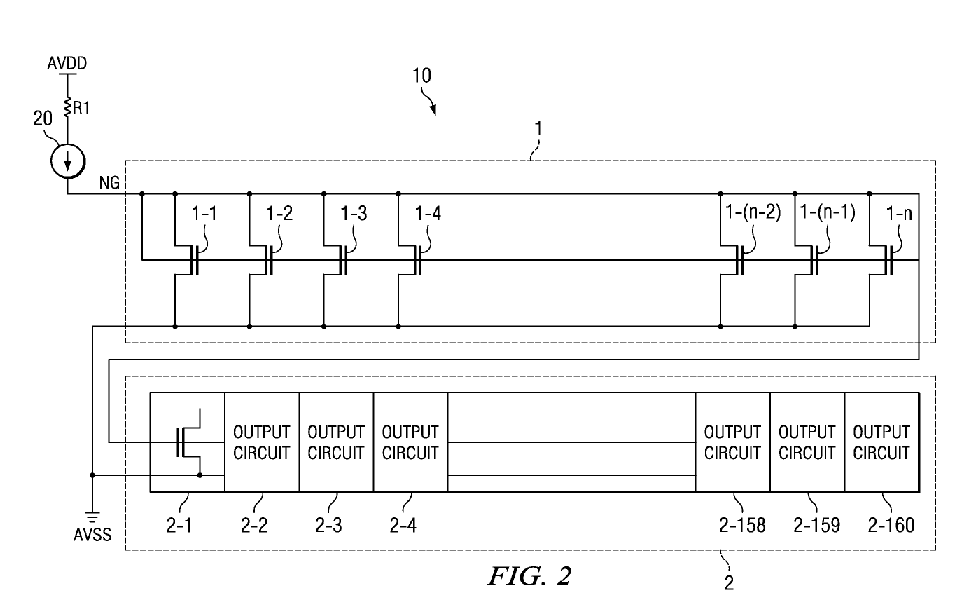

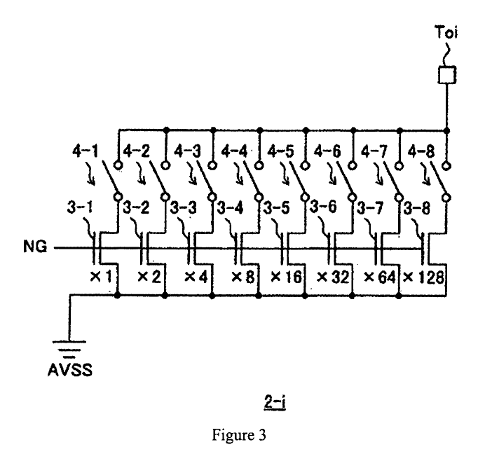

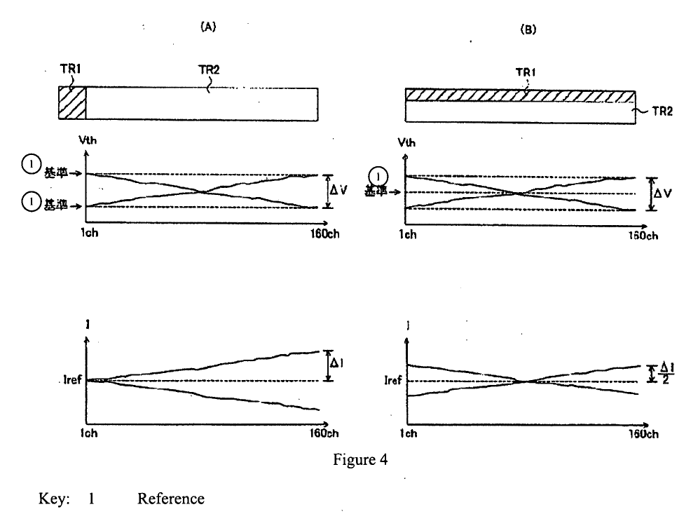

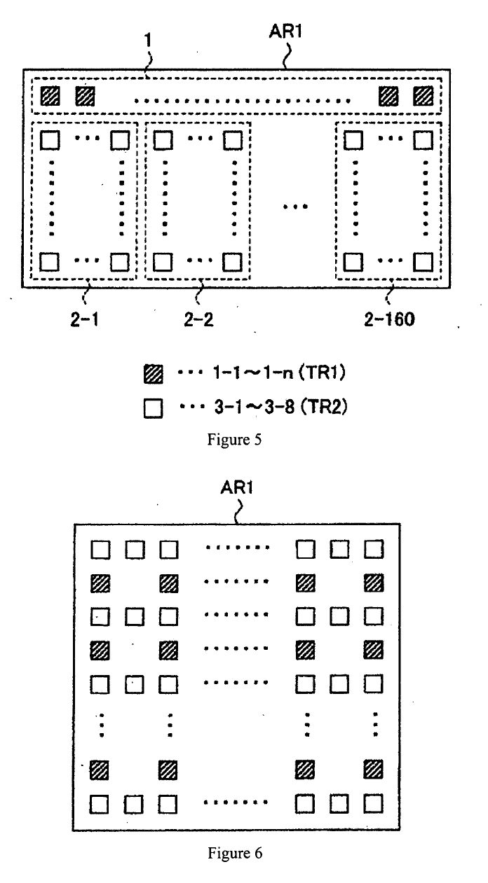

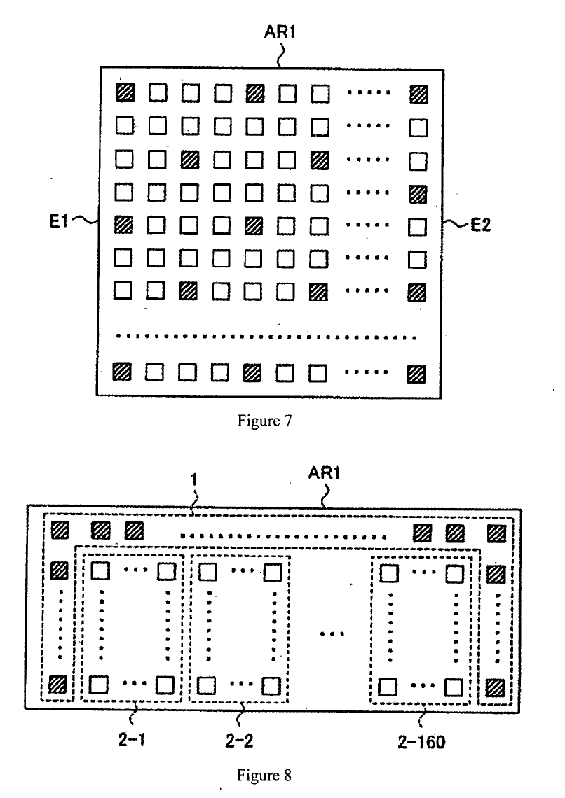

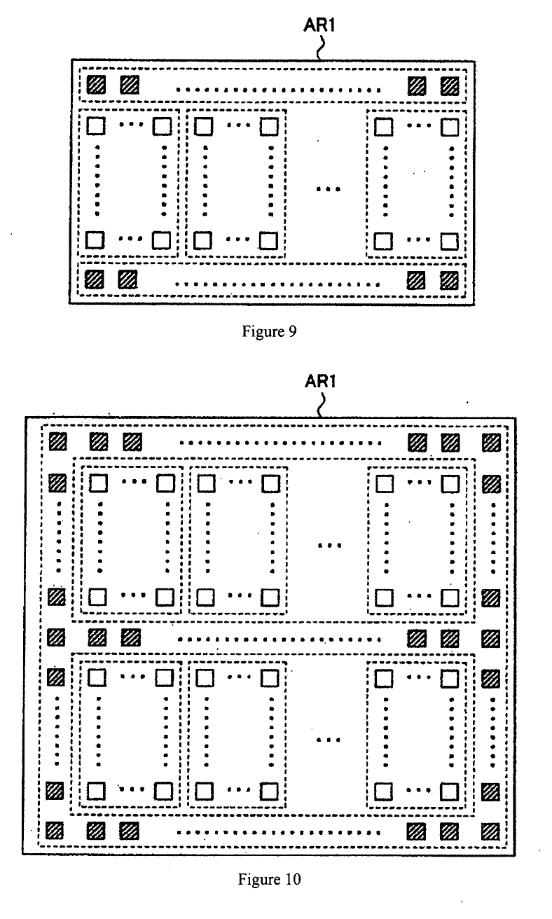

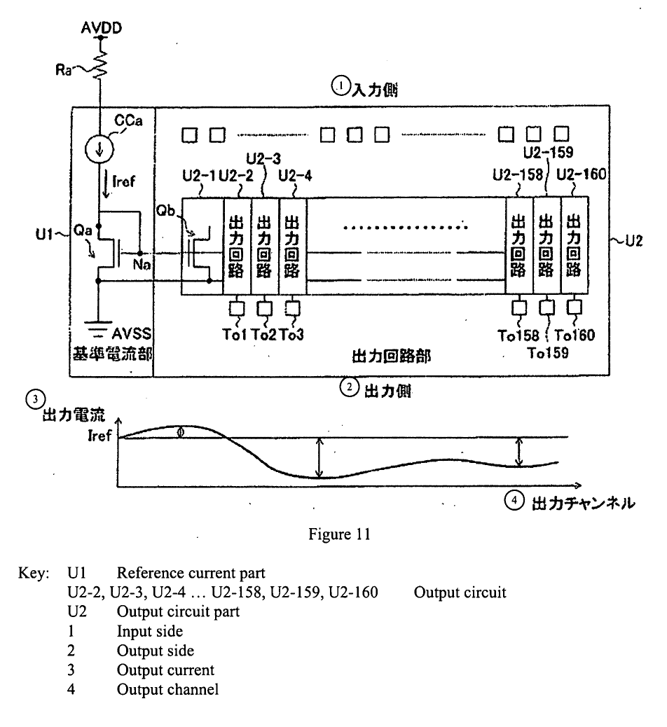

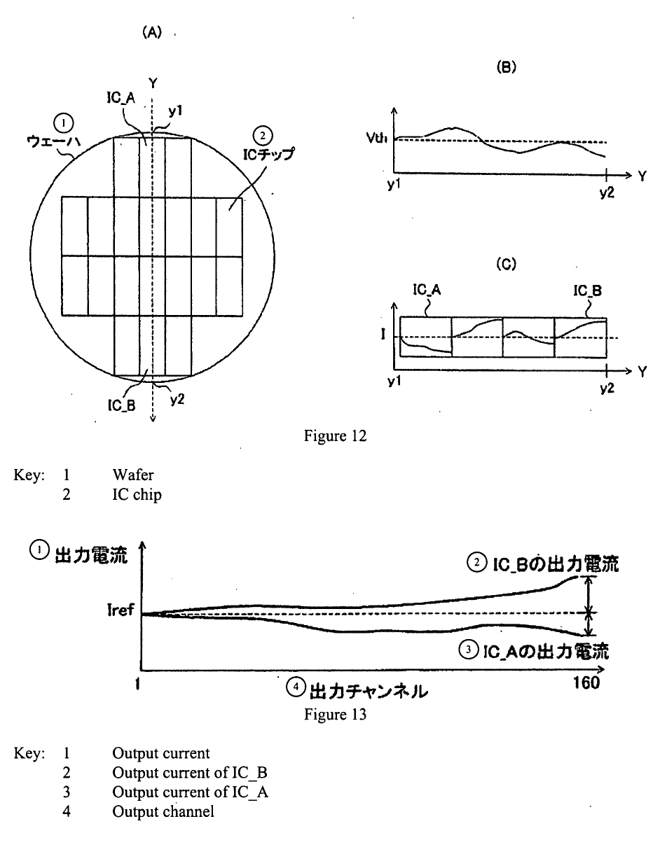

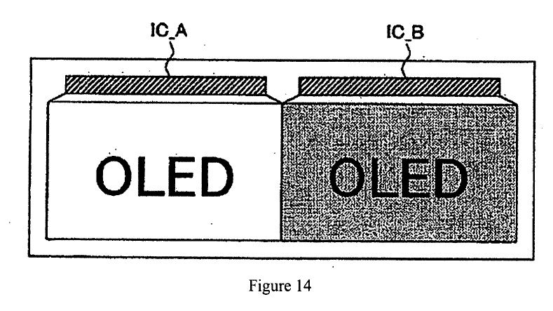

Indication of Fees:

| | |
|---|---|
| Prepayment Registration No.: | 014890 |
| Amount paid: | 16000 yen |

List of items submitted:

| | | |
|---|---|---|
| Item: | Claims | 1 |
| Item: | Specification | 1 |
| Item: | Drawing | 1 |
| Item: | Abstract | 1 |

| | |
|---|---|
| Comprehensive power of attorney No.: | 9102925 |

1. A current driving circuit characterized by the following facts: the current driving circuit has
a reference current generating circuit that generates a reference current,
a bias voltage generating circuit that includes plural first transistors connected in parallel with one another, inputs the aforementioned reference current to the parallel circuit of the first transistors, generates a bias voltage corresponding to the aforementioned reference current across the parallel circuit, and has a current corresponding to the bias voltage flowing through each of the first transistors,
plural second transistors that generate driving current corresponding to the bias voltage generated in the aforementioned bias voltage generating circuit;
the aforementioned plural first transistors and the aforementioned plural second transistors are formed and distributed in a common region on a semiconductor substrate.

2. The current driving circuit described in claim 1 characterized by the fact that the aforementioned plural first transistors and plural second transistors are arranged in one or more rows extending in the length direction of the aforementioned common region.

3. The current driving circuit described in claim 2 characterized by the fact that the one or more rows of the aforementioned first transistors and the one or more rows of the aforementioned second transistors are arranged alternately in the aforementioned common region.

4. The current driving circuit described in claim 2 or 3 characterized by the fact that the aforementioned first and second transistors are arranged at equal intervals in the rows extending in the aforementioned length direction.

5. The current driving circuit described in claim 2 or 3 characterized by the fact that at least some of the aforementioned plural first transistors are arranged in the same row as the aforementioned second transistors.

6. The current driving circuit described in claim 2, 3, 4, or 5 characterized by the fact that some of the aforementioned plural first transistors are formed at one or both ends of the row of the aforementioned second transistors.

7. A current driving circuit characterized by the following facts: the current driving circuit has
a reference current generating part, which has plural first transistors connected in parallel with each other and generates a reference current, and
plural driving current supply parts, which has second transistors connected to the aforementioned plural first transistors, respectively, and supply driving currents corresponding to the aforementioned reference current;
the aforementioned plural driving current supply parts are arranged along the length direction of a rectangular substrate;
the aforementioned plural first transistors are distributed and arranged along the length direction of the aforementioned semiconductor substrate.

8. The current driving circuit described in claim 7 characterized by the fact that the aforementioned plural first transistors are distributed and arranged in a region adjacent to the region where the aforementioned plural driving current supply parts are arranged.

9. The current driving circuit described in claim 7 characterized by the fact that the aforementioned plural first transistors and the aforementioned plural second transistors are mixed and are distributed and arranged along the length direction of the aforementioned semiconductor substrate.

10. The current driving circuit described in claim 7, 8, or 9 characterized by the fact that the aforementioned plural first transistors and the aforementioned second transistors constitute a current mirror circuit.
